(19) United States
(12) Patent Application Publication
(10) Pub. No.: US 2025/0271904 A1
(43) Pub. Date: Aug. 28, 2025

(54) PROTECTIVE PAD AND ELECTRONIC DEVICE

(71) Applicant: Getac Technology Corporation, New Taipei (TW)

(72) Inventor: CHIA-LUNG CHUNG, Taipei (TW)

(21) Appl. No.: 18/768,143

(22) Filed: Jul. 10, 2024

(30) Foreign Application Priority Data
Feb. 23, 2024 (CN) 202410200212.8

(51) Int. Cl. G06F 1/16

(52) U.S. Cl. CPC G06F 1/1656; G06F 1/1626

(57) ABSTRACT

A protective pad configured to be disposed on a device body having at least one first engaging structure, and include a pad body and at least one second engaging structure. The pad body includes a first side portion, a second side portion and a connecting portion, wherein the first side portion and the second side portion are connected to two opposite sides of the connecting portion. The first side portion and the second side portion protrude toward different directions. The at least one second engaging structure is disposed on the first side portion or the second side portion. The at least one first engaging structure and the at least one second engaging structure are matching each other. The at least one second engaging structure is configured to be engaged with the at least one first engaging structure.

### CROSS-REFERENCE TO RELATED APPLICATIONS

This non-provisional application claims priority under 35 U.S.C. § 119 (a) on Patent Application No(s). 202410200212.8 filed in China, on Feb. 23, 2024, the entire contents of which are hereby incorporated by reference.

### TECHNICAL FIELD

The present disclosure relates to a protective pad, more particularly to a protective pad disposed on an electronic device.

### BACKGROUND

Electronic devices such as smartphones, tablet computers or notebook computers, have become indispensable electronic products in daily life since the electronic devices are easy to carry so that users can do various tasks via the electronic devices anytime and anywhere. With technology advancing and electronic components becoming increasingly sophisticated, most electronic devices are not shock-resistant. When the fragile edges or corners of the electronic devices encounter impacts, the display panel and internal electronic components of the electronic devices can be easily damaged.

Generally, some electronic devices have a basic shockproof design. For example, users may add protective pads on the corners of the electronic devices to mitigate the impact of collisions. However, conventional protective pads often cannot be installed accurately on the electronic devices due to misalignment, leading to assembly inconvenience. Therefore, improving the accuracy of installing protective pads on the electronic devices is one of the problems that researchers need to address.

### SUMMARY

The present disclosure provides a protective pad and an electronic device configured to improve the accuracy of installing protective pads on electronic devices.

One embodiment of the present disclosure provides a protective pad configured to be disposed on a device body having at least one first engaging structure. The protective pad includes a pad body and at least one second engaging structure. The pad body includes a first side portion, a second side portion and a connecting portion, wherein the first side portion and the second side portion are connected to two opposite sides of the connecting portion. The first side portion and the second side portion protrude toward different directions. The at least one second engaging structure is disposed on the first side portion or the second side portion. The at least one first engaging structure and the at least one second engaging structure are matching each other. The at least one second engaging structure is configured to be engaged with the at least one first engaging structure.

Another embodiment of the present disclosure provides an electronic device including a device body and at least one protective pad. The device body includes at least one first engaging structure. The at least one protective pad is disposed on the device body, and includes a pad body and at least one second engaging structure. The pad body includes a first side portion, a second side portion and a connecting portion. The first side portion and the second side portion are connected to two opposite sides of the connecting portion. The first side portion and the second side portion protrude toward different directions. The at least one second engaging structure is disposed on the first side portion or the second side portion. The at least one first engaging structure and the at least one second engaging structure are matching each other. The at least one second engaging structure is engaged with the at least one first engaging structure.

According to the protective pad and the electronic device disclosed by the above embodiments, the protective pad includes the at least one second engaging structure, and the at least one first engaging structure is engaged with the at least one second engaging structure. Thus, the protective pad can be pre-positioned on the device body. Therefore, before the protective pad is fixed to the device body, the protective pad can be accurately aligned via the engagement between the at least one first engaging structure and the at least one second engaging structure so as to prevent misalignment during the assembly of the protective pad onto the device body. Consequently, the protective pad can be easily fixed to the device body.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of an electronic device in accordance with a first embodiment of the present disclosure;

FIG. 2 is an exploded view of the electronic device in FIG. 1;

FIG. 3 is an exploded and partial cross-sectional view of the electronic device in FIG. 1;

FIG. 4 is a side view of a protective pad of the electronic device in FIG. 1;

FIG. 5 is another side view of the protective pad of the electronic device in FIG. 1;

FIG. 6 is a partial cross-sectional view showing the protective pad and the device body of the electronic device in FIG. 1 before the protective pad is assembled onto the device body;

FIG. 7 is a partial cross-sectional view showing that the protective pad is assembled on the device body of the electronic device in FIG. 1;

FIG. 8 is a partial cross-sectional view showing that the protective pad is fixed to the device body of the electronic device in FIG. 1 via fasteners; and

FIG. 9 is a top view of a protective pad in accordance with a second embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

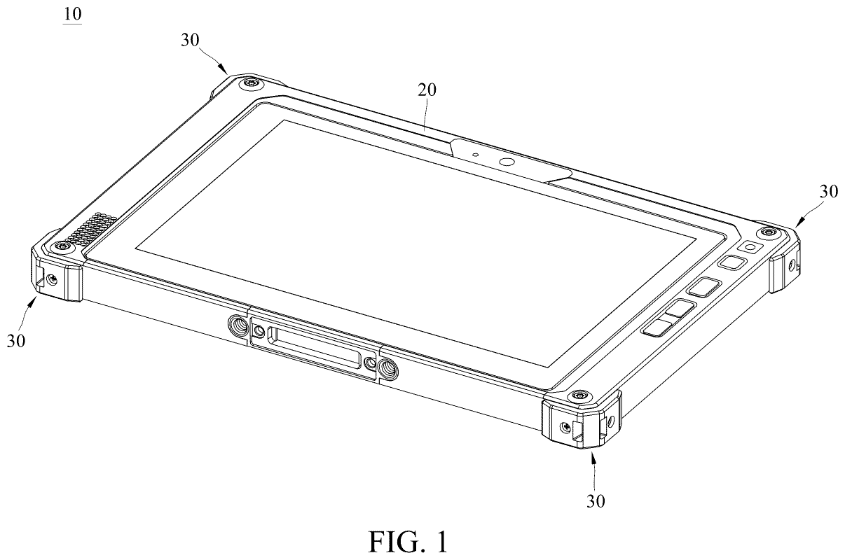

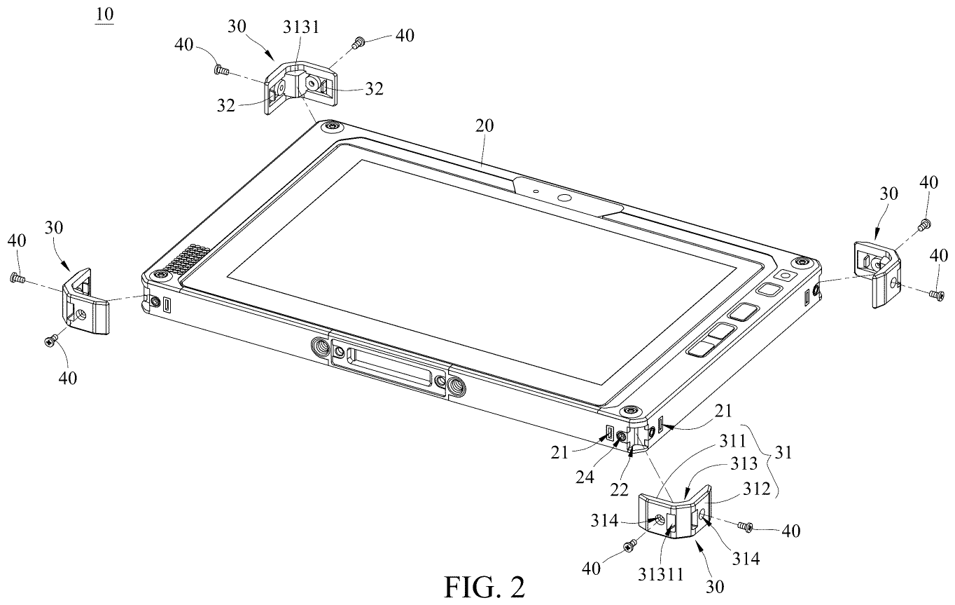

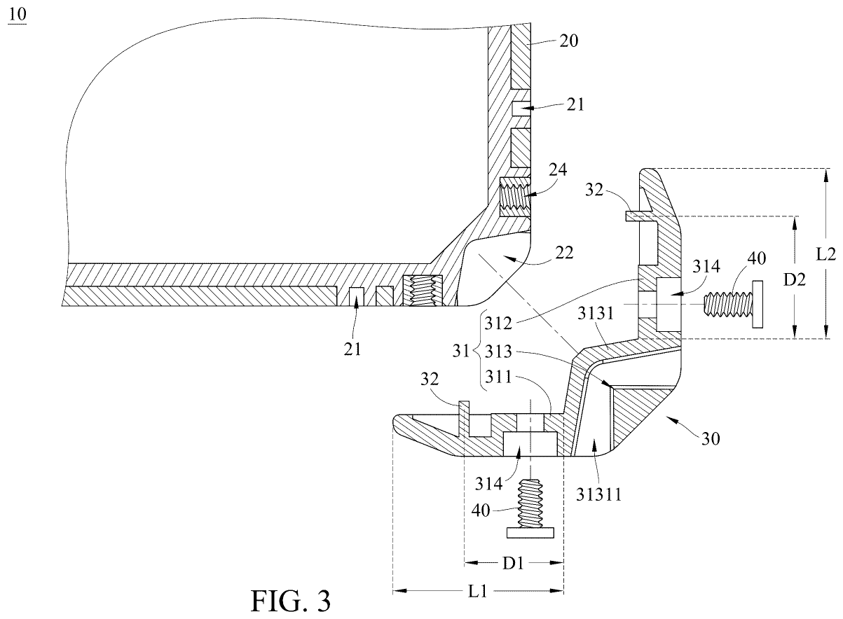

Please refer to FIG. 1 to FIG. 3, where FIG. 1 is a perspective view of an electronic device 10 in accordance with a first embodiment of the present disclosure, FIG. 2 is an exploded view of the electronic device 10 in FIG. 1, and FIG. 3 is an exploded and partial cross-sectional view of the electronic device 10 in FIG. 1.

In this embodiment, the electronic device 10 includes a device body 20 and four protective pads 30. The device body 20 is, for example, a tablet computer, but the present disclosure is not limited thereto. In other embodiments, the device body may be, for example, at least a part of a notebook computer or a smartphone. Each corner of the device body 20 includes two first engaging structures 21. The two first engaging structures 21 are, for example, engaging recesses. The present invention is not limited to the quantity of the first engaging structures 21. In other embodiments, each corner of the device body may include one first engaging structure.

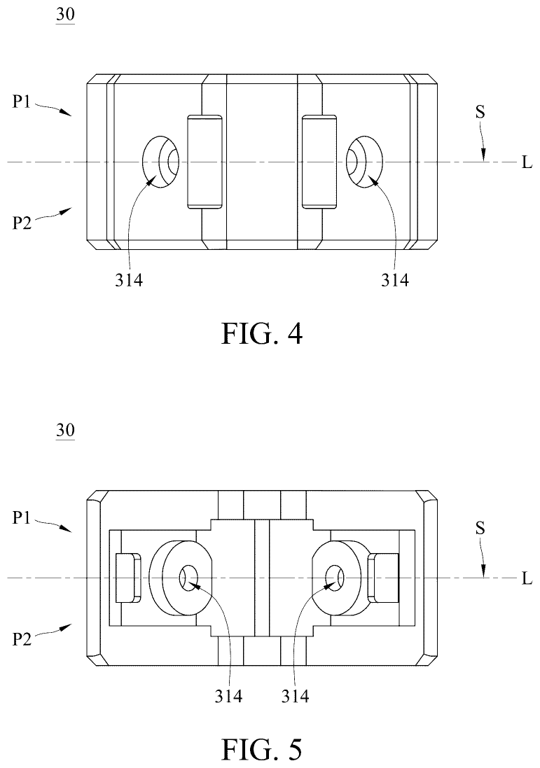

Please refer to FIG. 1 to FIG. 5, where FIG. 4 is a side view of the protective pad 30 of the electronic device 10 in FIG. 1, and FIG. 5 is another side view of the protective pad of 30 the electronic device 10 in FIG. 1.

The protective pads 30 are the same in structure. The protective pads 30 are disposed on the device body 20, and each of the protective pads 30 includes a pad body 31 and two second engaging structures 32. The pad body 31 includes a first side portion 311, a second side portion 312 and a connecting portion 313. A length L1 of the first side portion 311 is, for example, equal to a length L2 of the second side portion 312. The first side portion 311 and the second side portion 312 are connected to two opposite sides of the connecting portion 313, and protrude toward different directions.

The second engaging structures 32 are, for example, engaging protrusions, and are, for example, made of plastic materials. The second engaging structures 32 are disposed on the first side portion 311 and the second side portion 312, respectively, and protrude toward different directions. Distance D1 and D2 from the connecting portion 313 to each of the second engaging structures 32 may be identical. The first engaging structures 21 and the second engaging structures 32 are a recess and a protrusion matching each other, and the second engaging structures 32 are engaged with the first engaging structures 21, respectively. The present invention is not limited to the quantity of the second engaging structures 32, as long as the quantity of the second engaging structures 32 correspond to the quantity of the first engaging structures 21.

In this embodiment, the electronic device 10 may include a plurality of fasteners 40. The device body 20 has a plurality of fastening holes 24. The pad body 31 has a plurality of fastening holes 314. The fasteners 40 are, for example, screws, and the fastening holes 24 and 314 are, for example, screw holes. The fastening holes 314 are located on the first side portion 311 and the second side portion 312, respectively. The fasteners 40 pass through the fastening holes 314 and are fastened into the fastening holes 24 of the device body 20, respectively, so that the protective pads 30 can be fixed to the device body 20 more firmly.

In this embodiment, a reference plane S is defined as parallel to a surface of the device body 20 where a display panel (not shown) is disposed, and passing through a central line L of the fastening holes 314. Each of the protective pads 30 is divided into a first portion P1 and a second portion P2 via the reference plane S. The first portion P1 and the second portion P2 are in planar symmetry relative to the reference plane S.

In this embodiment, each of the protective pads 30 includes the second engaging structures 32 protruding toward different directions, and the first engaging structures 21 are engaged with the second engaging structures 32 along different direction, respectively. Thus, the second engaging structures 32 clamp onto the corners of the device body 20, such that the protective pad 30 can be pre-positioned on the device body 20. Therefore, before the protective pad 30 is fixed to the device body 20, the protective pad 30 can be accurately aligned via the engagement between the first engaging structures 21 and the second engaging structures 32 so as to prevent misalignment during the assembly of the protective pad 30 onto the device body 20. Consequently, the protective pad 30 can be easily fixed to the device body 20 using the fasteners 40.

In addition, each of the protective pads 30 is divided into a first portion P1 and a second portion P2 via the reference plane S, and the first portion P1 and the second portion P2 are in planar symmetry relative to the reference plane S, such that the protective pads 30 are the same in structure. Therefore, manufacturers can produce the protective pads 30 using a single mold, eliminating the need for additional molds and thus reducing production costs.

In this embodiment, the connecting portion 313 of the pad body 31 may include an engaging portion 3131. The engaging portion 3131 extends into a space between the first side portion 311 and the second side portion 312. The device body 20 may further include an engaging part 22. The engaging portion 3131 and the engaging part 22 are a restricting protrusion and a restricting recess matching each other, and the engaging portion 3131 is engaged with the engaging part 22. Accordingly, the protective pads 30 can be securely fixed to the device body 20.

In this embodiment, the engaging portion 3131 of the connecting portion 313 has a through hole 31311. The through hole 31311 is configured for a strap (not shown) to be disposed through, such that users can easily carry the electronic device 10 via the strap, thereby improving the convenience of transporting the electronic device 10.

In this embodiment, Distance D1 and D2 from the connecting portion 313 to each of the second engaging structures 32 may be identical, but the present invention is not limited thereto. In other embodiments, distance from the connecting portion to each of the second engaging structures may be different.

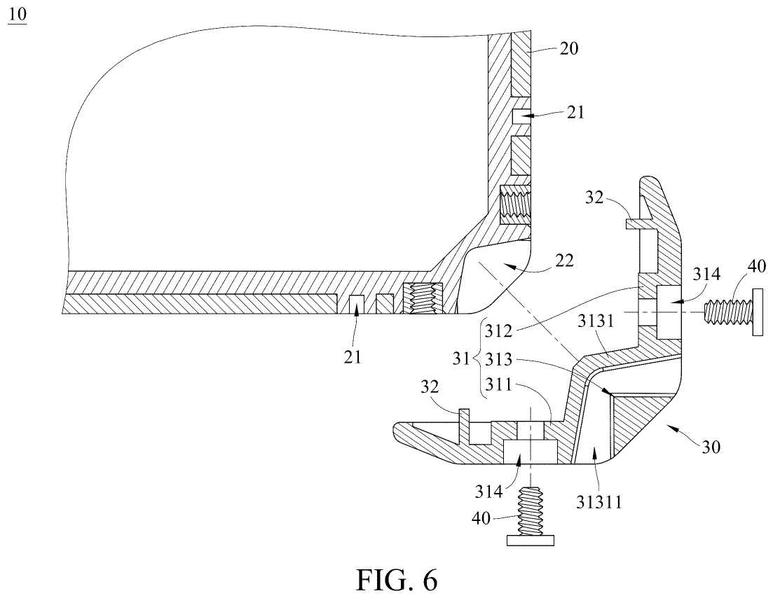

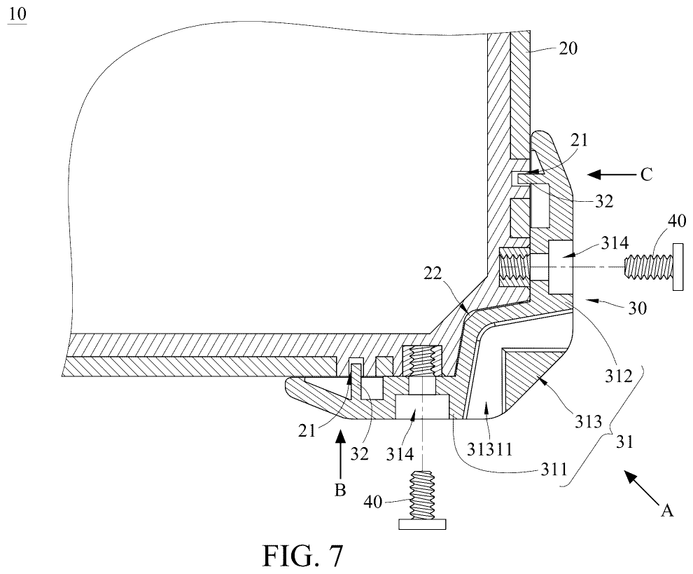

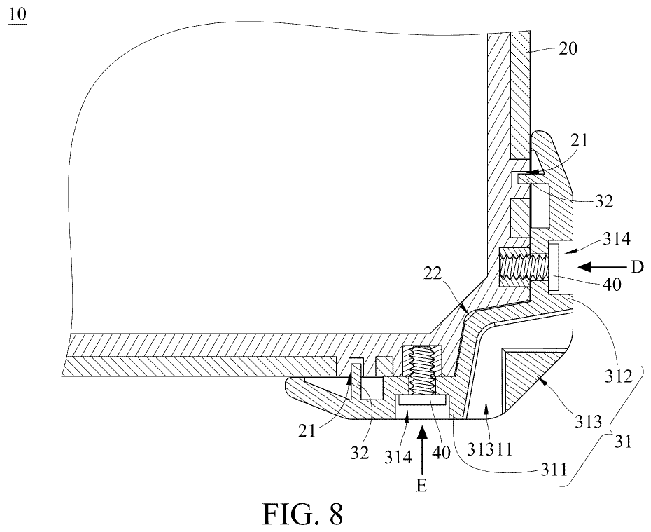

Please refer to FIG. 6 to FIG. 8, where FIG. 6 is a partial cross-sectional view showing the protective pad 30 and the device body 20 of the electronic device 10 in FIG. 1 before the protective pad 30 is assembled onto the device body 20, FIG. 7 is a partial cross-sectional view showing that the protective pad 30 is assembled onto the device body 20 of the electronic device 10 in FIG. 1, and FIG. 8 is a partial cross-sectional view showing that the protective pad 30 is fixed to the device body 20 of the electronic device 10 in FIG. 1 via fasteners.

As shown in FIG. 6, one of the protective pads 30 is shown as an example, and the protective pad 30 and the device body 20 are separated. That is, the protective pad 30 has not yet been assembled onto the device body 20 of the electronic device 10. As shown in FIG. 7, when the protective pad 30 is required to be assembled onto the device body 20, firstly, the protective pad 30 is moved toward the device body 20 along a direction A, and the second engaging structures 32 of the protective pad 30 are engaged with the first engaging structures 21 of the device body 20 along directions B and C, respectively. At this time, the protective pad 30 is pre-positioned on the device body 20 via the engagement of the first engaging structures 21 and the second engaging structures 32. As shown in FIG. 8, then, the fasteners 40 passes through the fastening holes 314 of the pad body 31 and are fastened into the fastening holes 24 of the device body 20 along directions D and E, respectively. Accordingly, the protective pad 30 can be fixed to the device body 20 firmly.

On the other hand, when the protective pad 30 is required to be removed from the device body 20, firstly, the fasteners 40 are removed along directions opposite to the directions D and E. Then, the second engaging structures 32 are disengaged from the first engaging structures 21 along directions opposite to the directions B and C, respectively, such that the positioning of the protective pad 30 to the device body 20 can be released, and then the protective pad 30 can be separated from the device body 20 along a direction opposite to the direction A. Consequently, the protective pad 30 is removed from the device body 20.

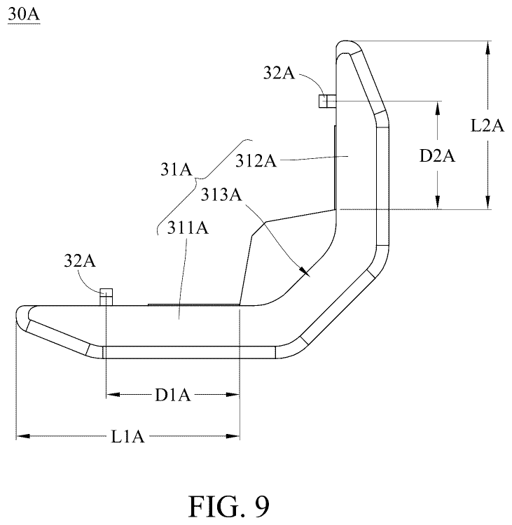

In the first embodiment, the length L1 of the first side portion 311 is the same as the length L2 of the second side portion 312, and the distance D1 between one of the second engaging structures 32 and the connecting portion 313 is the same as the distance D2 between the other second engaging structure 32 and the connecting portion 313, but the present invention is not limited thereto. In other embodiments, please refer to FIG. 9, which is a top view of a protective pad 30A in accordance with a second embodiment of the present disclosure. One of the protective pads 30A is shown as an example, the protective pad 30A of this embodiment is similar to the protective pad 30 of the first embodiment, the main difference between them will be described below, and the same parts between them can be referred to the aforementioned paragraphs with the reference to FIG. 1 to FIG. 8 and will not be repeatedly introduced hereinafter.

In this embodiment, a length L1A of the first side portion 311A is different from a length L2A of the second side portion 312A, and distance D1A and D2A from the connecting portion 313A to each of the second engaging structures 32A may be different., such that the protective pads 30A can be correspondingly disposed on the corners of the device body (not shown), respectively, which prevents incorrect assembly of the protective pads 30A by the users, thereby achieving a foolproof effect.

According to the protective pad and the electronic device disclosed by the above embodiments, each of the protective pads includes the second engaging structures protruding toward different directions, and the first engaging structures are engaged with the second engaging structures along different direction, respectively. Thus, the second engaging structures clamp onto the corners of the device body, such that the protective pad can be pre-positioned on the device body. Therefore, before the protective pad is fixed to the device body, the protective pad can be accurately aligned via the engagement between the first engaging structures and the second engaging structures so as to prevent misalignment during the assembly of the protective pad onto the device body. Consequently, the protective pad can be easily fixed to the device body using the fasteners.

In addition, each of the protective pads is divided into a first portion and a second portion via the reference plane, and the first portion and the second portion are in planar symmetry relative to the reference plane, such that the protective pads are the same in structure. Therefore, manufacturers can produce the protective pads using a single mold, eliminating the need for additional molds and thus reducing production costs.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A protective pad, configured to be disposed on a device body having at least one first engaging structure, and the protective pad comprising:
a pad body, comprising a first side portion, a second side portion and a connecting portion, wherein the first side portion and the second side portion are connected to two opposite sides of the connecting portion, and the first side portion and the second side portion protrude toward different directions; and
at least one second engaging structure, disposed on the first side portion or the second side portion, wherein the at least one first engaging structure and the at least one second engaging structure are matching each other, and the at least one second engaging structure is configured to be engaged with the at least one first engaging structure.

2. The protective pad according to claim 1, wherein a length of the first side portion is equal to a length of the second side portion.

3. The protective pad according to claim 1, wherein the protective pad comprises two second engaging structures, the two second engaging structures are disposed on the first side portion and the second side portion, respectively, and the two second engaging structures protrude toward different directions.

4. The protective pad according to claim 3, wherein distances from the connecting portion to each of the two second engaging structures are identical.

5. The protective pad according to claim 3, wherein distances from the connecting portion to each of the two second engaging structures are different.

6. The protective pad according to claim 1, wherein the pad body has at least one fastening hole, and the at least one fastening hole is located on the first side portion or the second side portion.

7. The protective pad according to claim 6, wherein a reference plane is defined as passing through a central line of the at least one fastening hole, the protective pad is divided into a first portion and a second portion via the reference plane, and the first portion and the second portion are in planar symmetry relative to the reference plane.

8. The protective pad according to claim 1, wherein the connecting portion comprises an engaging portion, and the engaging portion extends into a space between the first side portion and the second side portion.

9. The protective pad according to claim 1, wherein the connecting portion has a through hole.

10. An electronic device, comprising:
a device body, comprising at least one first engaging structure; and
at least one protective pad, disposed on the device body and comprising:
a pad body, comprising a first side portion, a second side portion and a connecting portion, wherein the first side portion and the second side portion are connected to two opposite sides of the connecting portion, and the first side portion and the second side portion protrude toward different directions; and
at least one second engaging structure, disposed on the first side portion or the second side portion, wherein the at least one first engaging structure and the at least one second engaging structure are matching each other, and the at least one second engaging structure is engaged with the at least one first engaging structure.

11. The electronic device according to claim 10, wherein a length of the first side portion is equal to a length of the second side portion.

12. The electronic device according to claim 10, wherein the protective pad comprises two second engaging structures, the two second engaging structures are disposed on the first side portion and the second side portion, respectively, and the two second engaging structures protrude toward different directions.

13. The electronic device according to claim 12, wherein distances from the connecting portion to each of the two second engaging structures are identical.

14. The electronic device according to claim 12, wherein distances from the connecting portion to each of the two second engaging structures are different.

15. The electronic device according to claim 10, further comprising at least one fastener, wherein the pad body has at least one fastening hole, the at least one fastening hole is located on the first side portion or the second side portion, and the at least one fastener is fastened into the at least one fastening hole to fix the at least one protective pad to the device body.

16. The electronic device according to claim 15, wherein a reference plane is defined as passing through a central line of the at least one fastening hole, the protective pad is divided into a first portion and a second portion via the reference plane, and the first portion and the second portion are in planar symmetry relative to the reference plane.

17. The electronic device according to claim 10, wherein the connecting portion comprises an engaging portion, and the engaging portion extends into a space between the first side portion and the second side portion, the device body further comprises an engaging part, and the engaging portion is engaged with the engaging part.

18. The electronic device according to claim 17, wherein the engaging portion extends into a space between the first side portion and the second side portion.

19. The electronic device according to claim 18, wherein the connecting portion of the at least one protective pad has a through hole.
